(19) United States
(12) Patent Application Publication
(10) Pub. No.: US 2017/0196096 A1
(43) Pub. Date: Jul. 6, 2017

(54) PRINTED WIRING BOARD AND METHOD FOR MANUFACTURING PRINTED WIRING BOARD

(71) Applicant: IBIDEN CO., LTD., Ogaki (JP)

(72) Inventors: Teruyuki ISHIHARA, Ogaki (JP); Ayumi SHIBATA, Ogaki (JP); Kosuke IKEDA, Ogaki (JP)

(73) Assignee: IBIDEN CO., LTD., Ogaki (JP)

(21) Appl. No.: 15/398,935

(22) Filed: Jan. 5, 2017

(30) Foreign Application Priority Data
Jan. 5, 2016 (JP) 2016-000565

(51) Int. Cl. H05K 3/46; H05K 1/18; H05K 3/06; H05K 3/40; H05K 1/11

(52) U.S. Cl. CPC H05K 3/4682; H05K 3/4007; H05K 1/113; H05K 3/061; H05K 1/181; H05K 3/4038; H05K 2201/04

(57) ABSTRACT

A printed wiring board includes a resin insulating layer, a projecting conductor layer formed on a surface of the resin insulating layer such that the projecting conductor layer is projecting from the surface of the resin insulating layer, and an integral conductor structure formed in the resin insulating layer and including a via conductor portion and an embedded conductor layer portion such that the embedded conductor layer portion is embedded in the resin insulating layer on the opposite side of the resin insulating layer with respect to the projecting conductor layer and has an exposed surface exposed from the resin insulating layer and the via conductor portion is formed through the resin insulating layer and is connecting the embedded conductor layer portion and projecting conductor layer. The projecting conductor layer and integral conductor structure are formed such that the projecting conductor layer and integral conductor structure are individual conductor structures.

### CROSS-REFERENCE TO RELATED APPLICATIONS

The present application is based upon and claims the benefit of priority to Japanese Patent Application No. 2016-000565, filed Jan. 5, 2016, the entire contents of which are incorporated herein by reference.

### BACKGROUND OF THE INVENTION

Field of the Invention

The present invention relates to a printed wiring board and a method for manufacturing the printed wiring board.

Description of Background Art

Japanese Patent Laid-Open Publication No. 2014-27250 describes a coreless substrate and a method for manufacturing the coreless substrate. The entire contents of this publication are incorporated herein by reference.

### SUMMARY OF THE INVENTION

According to one aspect of the present invention, a printed wiring board includes a resin insulating layer, a projecting conductor layer formed on a surface of the resin insulating layer such that the projecting conductor layer is projecting from the surface of the resin insulating layer, and an integral conductor structure formed in the resin insulating layer and including a via conductor portion and an embedded conductor layer portion such that the embedded conductor layer portion is embedded in the resin insulating layer on the opposite side of the resin insulating layer with respect to the projecting conductor layer and has an exposed surface exposed from the resin insulating layer and that the via conductor portion is formed through the resin insulating layer and is connecting the embedded conductor layer portion and the projecting conductor layer. The projecting conductor layer and the integral conductor structure are formed such that the projecting conductor layer and the integral conductor structure are individual conductor structures.

According to another aspect of the present invention, a method for manufacturing a printed wiring board includes forming a plating resist on a surface of an intermediate wiring board such that the plating resist has an opening portion for an integral conductor structure including a via conductor portion and an embedded conductor layer portion, applying plating in the opening portion of the plating resist such that a plating film is formed in the opening portion of the plating resist, forming an etching resist for the via conductor portion of the integral conductor structure on the plating film in the opening portion of the plating resist, reducing a thickness of an exposed portion of the plating film exposed from the etching resist such that the integral conductor structure including the via conductor portion and the embedded conductor layer portion is formed in the opening portion of the plating resist, removing the etching resist from the plating film, removing the plating resist from the intermediate wiring board, forming a resin insulating layer on the surface of the intermediate wiring board such that a surface of the via conductor has an exposed surface exposed from the resin insulating layer, and forming a projecting conductor layer on the resin insulating layer such that the projecting conductor layer connects to the exposed surface of the via conductor portion in the integral conductor structure.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1A-1C illustrate cross-sectional views of printed wiring boards according to second and third embodiments of the present invention;

FIG. 2A-2F are manufacturing process diagrams of the printed wiring board of the third embodiment;

FIG. 3A-3C are manufacturing process diagrams of the printed wiring board of the third embodiment;

FIG. 4A-4C are manufacturing process diagrams of the printed wiring board of the third embodiment;

FIG. 5A-5C are manufacturing process diagrams of the printed wiring board of the third embodiment;

FIG. 6A-6C are cross-sectional views of a printed wiring board according to a first embodiment of the present invention;

FIG. 6D is a plan view of a land; and

FIG. 6E is a manufacturing process diagram of the first embodiment.

### DETAILED DESCRIPTION OF THE EMBODIMENTS

The embodiments will now be described with reference to the accompanying drawings, wherein like reference numerals designate corresponding or identical elements throughout the various drawings.

### First Embodiment

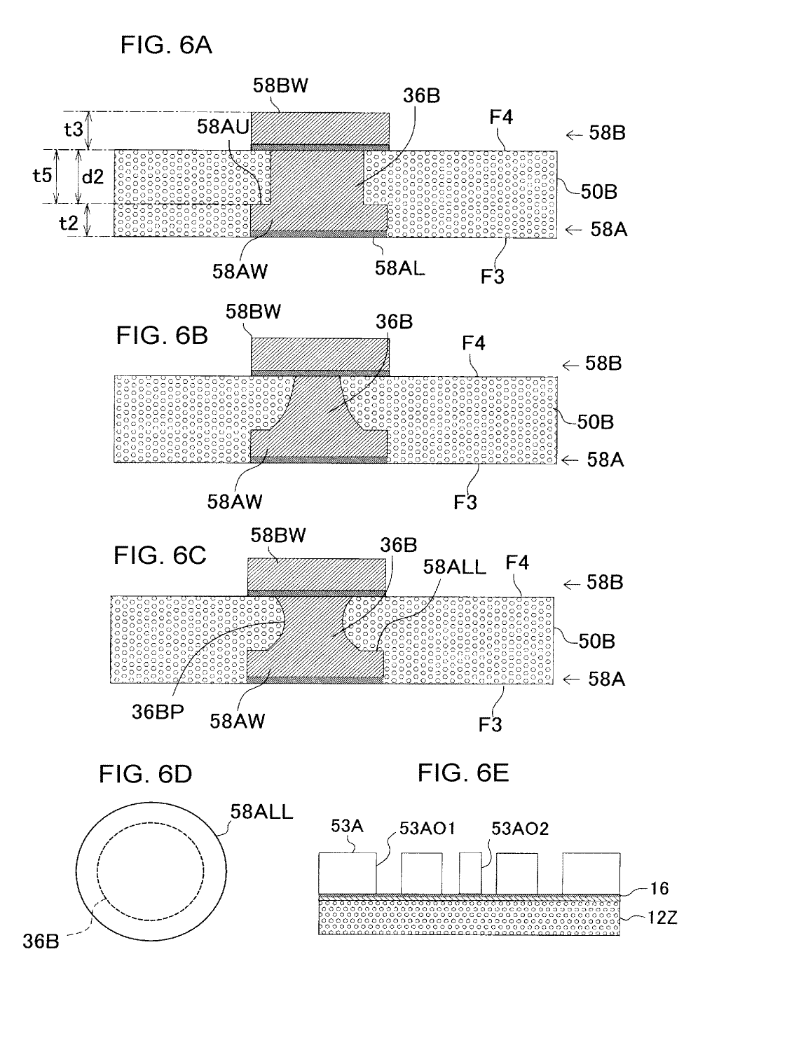

FIG. 6A illustrates a cross section of a printed wiring board 10 of a first embodiment. The printed wiring board 10 of the first embodiment includes: a second resin insulating layer (50B) that has a third surface (F3) and a fourth surface that is on an opposite side of the third surface (F3); a second conductor layer (58A) that is formed on the third surface (F3) of the second resin insulating layer (50B); a third conductor layer (58B) that is formed on the fourth surface (F4) of the second resin insulating layer (50B); and a second via conductor (36B) that penetrates the second resin insulating layer (50B) and connects the second conductor layer (58A) and the third conductor layer (58B).

The second resin insulating layer (50B) has a thickness (d2). The thickness (d2) is a distance between the second conductor layer (58A) and the third conductor layer (58B). The thickness (d2) is 1.5 μm or more and 3.5 μm or less. For example, the thickness (d2) is 2.5 μm.

The second conductor layer (58A) has multiple conductor circuits (58AW). The second conductor layer (58A) has an upper surface (58AU) and a lower surface (58AL) that is on an opposite side of the upper surface (58AU). The second conductor layer (58A) is embedded in the second resin insulating layer such that the lower surface (58AL) is exposed from the third surface (F3). The second conductor layer (58A) has a thickness (t2). The thickness (t2) is 1.5 μm or more and 3.5 μm or less. For example, the thickness (t2) is 2.5 μm.

The second via conductor (36B) and the second conductor layer (58A) are integrally formed. The second via conductor (36B) is formed on a conductor circuit (58AW) in the second conductor layer (58A). The second via conductor (36B) and the conductor circuit (58AW) in the second conductor layer (58A) are integrally formed. The second via conductor (36B) and the conductor circuit (58AW) are formed from one plating film. Therefore, reliability of connection between the conductor circuit (58AW) and the second via conductor (36B) is high. For example, by thinning an outer periphery of a plating film by etching, the second via conductor (36B) and the conductor circuit (58AW) are formed one plating film.

In FIG. 6A, the second via conductor (36B) has a shape of a substantially circular cylinder. Examples of the shape of the second via conductor (36B) are illustrated in FIGS. 6B and 6C. In FIGS. 6B and 6C, a side surface of the second via conductor (36B) is curved. In FIG. 6B, the second via conductor (36B) is gradually increased in diameter from the third conductor layer (58B) toward the second conductor layer (58A). The second via conductor (36B) is increased in diameter from the fourth surface (F4) toward the third surface (F3). In FIG. 6C, the side surface of the second via conductor (36B) has an inflection point (36BP). The second via conductor (36B) is gradually reduced in diameter from the third conductor layer (58B) toward the inflection point (36BP), and is gradually increased in diameter from the inflection point (36BP) toward the second conductor layer (58A). The second resin insulating layer (50B) is unlikely to be peeled off from the second via conductor (36B). Migration is unlikely to occur. Insulation reliability of the printed wiring board 10 is increased. Even when the printed wiring board 10 warps, the second via conductor (36B) is likely to be able to follow the warping. Reliability of connection via the second via conductor (36B) can be increased. The second resin insulating layer (50B) is formed from resin only. Or, the second resin insulating layer (50B) is formed from resin and inorganic particles only. In this case, strength of the second resin insulating layer (50B) is low. Therefore, when the conductor circuit (58AW) and the second via conductor (36B) are embedded in one resin insulating layer, stress is likely to concentrate on an interface between the conductor circuit (58AW) and the second via conductor (36B). However, in the present embodiment, the second via conductor (36B) and the conductor circuit (58AW) are integrally formed. Therefore, the second via conductor (36B) is unlikely to be peeled off from the conductor circuit (58AW).

The second via conductor (36B) has a length (t5). The length (t5) is substantially equal to the thickness (d2).

The third conductor layer (58B) is formed on the fourth surface (F4) of the second resin insulating layer (50B). The third conductor layer (58B) projects from the fourth surface (F4) of the second resin insulating layer (50B). The third conductor layer (58B) and the second via conductor (36B) are individually formed. An interface exists between the third conductor layer (58B) and the second via conductor (36B). The third conductor layer (58B) has multiple conductor circuits (58BW) in the third conductor layer (58B). The conductor circuit (58BW) and the second via conductor (36B) are individually formed. The third conductor layer (58B) has a thickness (t3). The thickness (t3) is 1.5 μm or more and 3.5 μm or less. For example, the thickness (t3) is 2.5 μm.

### Second Embodiment

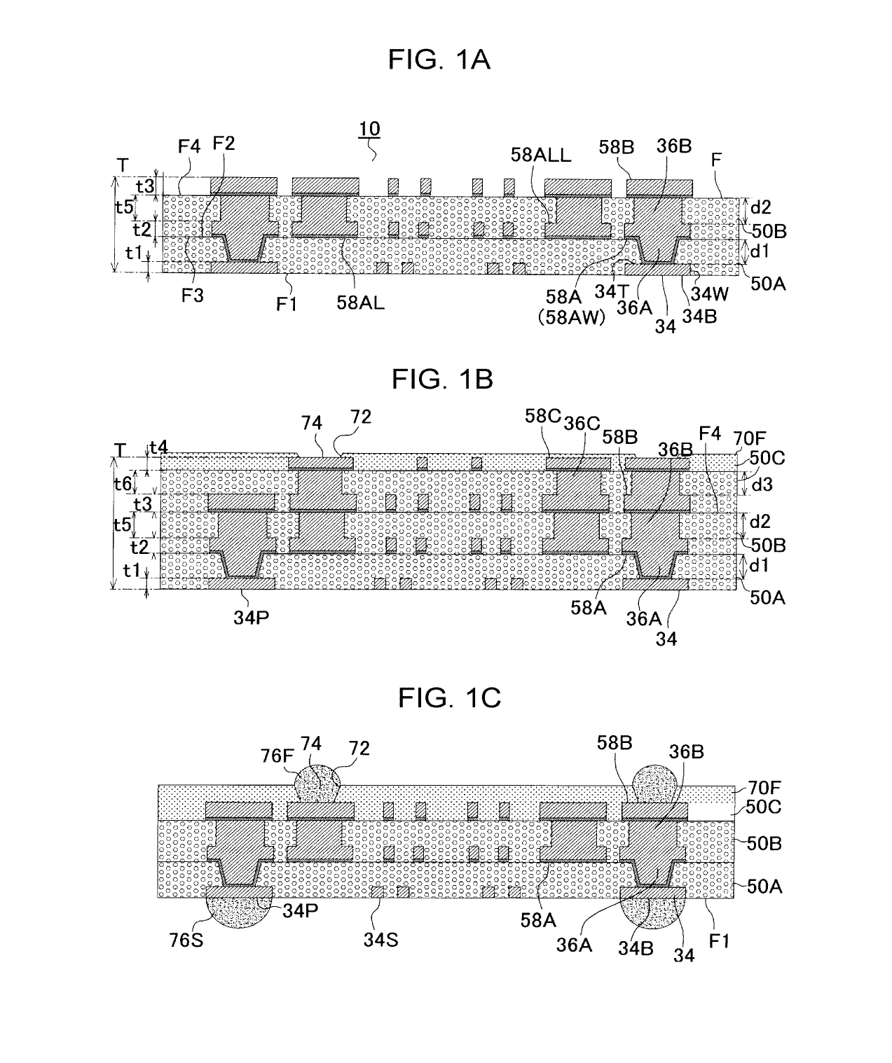

FIG. 1 A illustrates a cross-sectional view of a printed wiring board 10 of a second embodiment. The printed wiring board of the second embodiment is formed by adding to the printed wiring board of the first embodiment a first conductor layer 34, a first resin insulating layer (50A) on the first conductor layer 34, and a first via conductor (36A) that penetrates the first resin insulating layer (50A) and connects the first conductor layer 34 and the second conductor layer (58A).

The first resin insulating layer (50A) has a first surface (F1) and a second surface (F2) that is on an opposite side of the first surface (F1). The second conductor layer (58A) and the second resin insulating layer (50B) are formed on the second surface (F2). The second surface (F2) opposes the third surface (F3). The second surface (F2) and the lower surface (58AL) of the second conductor layer (58A) oppose each other. The first resin insulating layer (50A) is formed below the lower surface (58AL) of the second conductor layer (58A) and the third surface (F3) of the second resin insulating layer (50B). The first resin insulating layer (50A) is formed from resin only. Or, the first resin insulating layer (50A) is formed from resin and inorganic particles only. The first resin insulating layer (50A) has a thickness (d1). The thickness (d1) is a distance between the first conductor layer 34 and the second conductor layer (58A). The thickness (d1) is 1.5 μm or more and 3.5 μm or less. For example, the thickness (d1) is 2.5 μm.

The first conductor layer 34 has an upper surface (34T), a lower surface (34B) that is on an opposite side of the upper surface (34T), and a side surface (34W). The first conductor layer 34 is embedded in the first resin insulating layer (50A) such that only the lower surface (34B) is exposed from the first surface (F1). A thickness (t1) of the first conductor layer 34 is 1.5 μm or more and 3.5 μm or less. For example, the thickness (t1) is 2.5 μm.

As illustrated in FIG. 1A, the first via conductor (36A) is gradually reduced in diameter from the second conductor layer (58A) toward the first conductor layer 34. When the first via conductor (36A) is gradually reduced in diameter from the second conductor layer (58A) toward the first conductor layer 34 and the second via conductor is gradually reduced in diameter from the second conductor layer (58A) toward the third conductor layer (58B), symmetry of the via conductors (36A, 36B) that sandwich the second conductor layer (58A) is increased. Warpage of the printed wiring board can be reduced. When the first via conductor (36A) has the shape illustrated in FIG. 1A and the second via conductor (36B) has the shape illustrated in FIG. 6C, stress propagating via the first via conductor (36A) and the second conductor layer (58A) to the second via conductor (36B) is relaxed by the inflection point (36BP). Reliability of connection via the via conductors (36A, 36B) is increased.

The first via conductor (36A), the second via conductor (36B), and the conductor circuit (58AW) in the second conductor layer (58A) that is sandwiched by the first via conductor (36A) and the second via conductor (36B), are integrally formed. The first via conductor (36A), the second via conductor (36B) and the conductor circuit (58AW) are simultaneously formed. The first via conductor (36A), the second via conductor (36B) and the conductor circuit (58AW) are formed from the same plating film. Even when the printed wiring board has warpage, peeling is unlikely to occur between the first via conductor (36A) and the conductor circuit (58AW). Peeling is unlikely to occur between the second via conductor (36B) and the conductor circuit (58AW).

As illustrated in FIG. 1C, a solder bump (76S) can be formed on a lower surface (34B) of a conductor circuit (pad) (34P) in the first conductor layer 34 of the printed wiring board 10 of the first embodiment or the second embodiment. In FIG. 1C, the first conductor layer 34 has a wiring (34S) in addition to the pad (34P). Due to the pad (34P), the printed wiring board 10 of the second embodiment can be connected to another circuit substrate or an electronic component. Due to the wiring (34S), a signal or the like is transmitted in the first conductor layer 34. The first conductor layer 34 of the printed wiring board 10 of FIG. 1C has the pad (34P) and the wiring (34S). However, it is also possible that the first conductor layer 34 of the printed wiring board 10 of the second embodiment is formed by the pad (34P) only.

When the printed wiring board of the first embodiment is connected to another circuit substrate or an electronic component, the conductor circuit (58AW) in the second conductor layer (58A) functions as a pad. In this case, the second conductor layer (58A) can be formed by the pad only.

As illustrated in FIG. 1C, it is also possible that the printed wiring board 10 of the second embodiment has a solder resist layer (70F) on the second resin insulating layer (50B) and on the third conductor layer (58B). The solder resist layer (70F) has an opening 72, and the third conductor layer (58B) exposed by the opening 72 functions as an upper side pad 74. A solder bump (76F) is formed on the upper side pad 74. An IC chip is mounted on the printed wiring board 10 via the solder bump (76F). It is also possible that the printed wiring board 10 of the first embodiment has the solder resist layer (70F), the upper side pad 74 and the solder bump (76F) illustrated in FIG. 1C on the second resin insulating layer (50B) and the third conductor layer (58B).

FIG. 1B illustrates a printed wiring board 10 of a third embodiment. The printed wiring board 10 of the third embodiment has a third resin insulating layer (50C) that is formed on the second resin insulating layer (50B) and the third conductor layer (58B)of the second embodiment, a fourth conductor layer (58C) on the third resin insulating layer (50C). and a third via conductor (36C) that penetrates the third resin insulating layer (50C) and connects the third conductor layer (58B) and the fourth conductor layer (58C). The third resin insulating layer (50C) has a thickness (d3). The thickness (d3) is 1.5 μm or more and 3.5 μm or less. For example, the thickness (d3) is 2.5 μm. Each of the thicknesses (d1, d2, d3) of the resin insulating layers (50A, 50B, 50C) is a distance between the conductor layers sandwiching the resin insulating layer. The fourth conductor layer (58C) has a thickness (t4). The thickness (t4) is 1.5 μm or more and 3.5 μm or less. For example, the thickness (t4) is 2.5 μm. The third via conductor (36C) has a length (t6). The length (t6) is substantially equal to the thickness (d3).

The third via conductor (36C) has the same shape as the second via conductor (36B). Examples of the shape of the third via conductor (36C) are illustrated in FIG. 6A-6C.

The third via conductor (36C) and the third conductor layer (58B) are integrally formed. The third via conductor (36C) and the third conductor layer (58B) are simultaneously formed. The third via conductor (36C) and the third conductor layer (58B) are formed from the same plating film. Even when the printed wiring board has warpage, peeling is unlikely to occur between the third via conductor (36C) and the third conductor layer (58B).

As illustrated in FIGS. 6C and 6D, the conductor layer that is simultaneously formed with the via conductor has a land ((58ALL)) that is directly connected to the via conductor. FIG. 6D illustrates a plan view obtained by observing the via conductor and the land from above the via conductor. An outer periphery of the via conductor (36B) is depicted using a dotted line, and an outer periphery of the land ((58ALL)) is depicted using a solid line. A size of the land is larger than a size of the via conductor. The entire outer periphery of the land is exposed from the via conductor.

As illustrated in FIG. 1B, the solder resist layer (70F) is formed on the third resin insulating layer (50C) and the fourth conductor layer (58C). The solder resist layer (70F) has the opening 72 that exposes the upper side pad 74. The solder bump (76F) can be formed on the upper side pad 74. An electronic component such as an IC chip (not illustrated in the drawings) is mounted on the printed wiring board via the solder bump (76F). The printed wiring board 10 of the first embodiment or the second embodiment may also have the solder resist layer (70F) on the second resin insulating layer (50B).

### Method for Manufacturing Printed Wiring Board of Third Embodiment

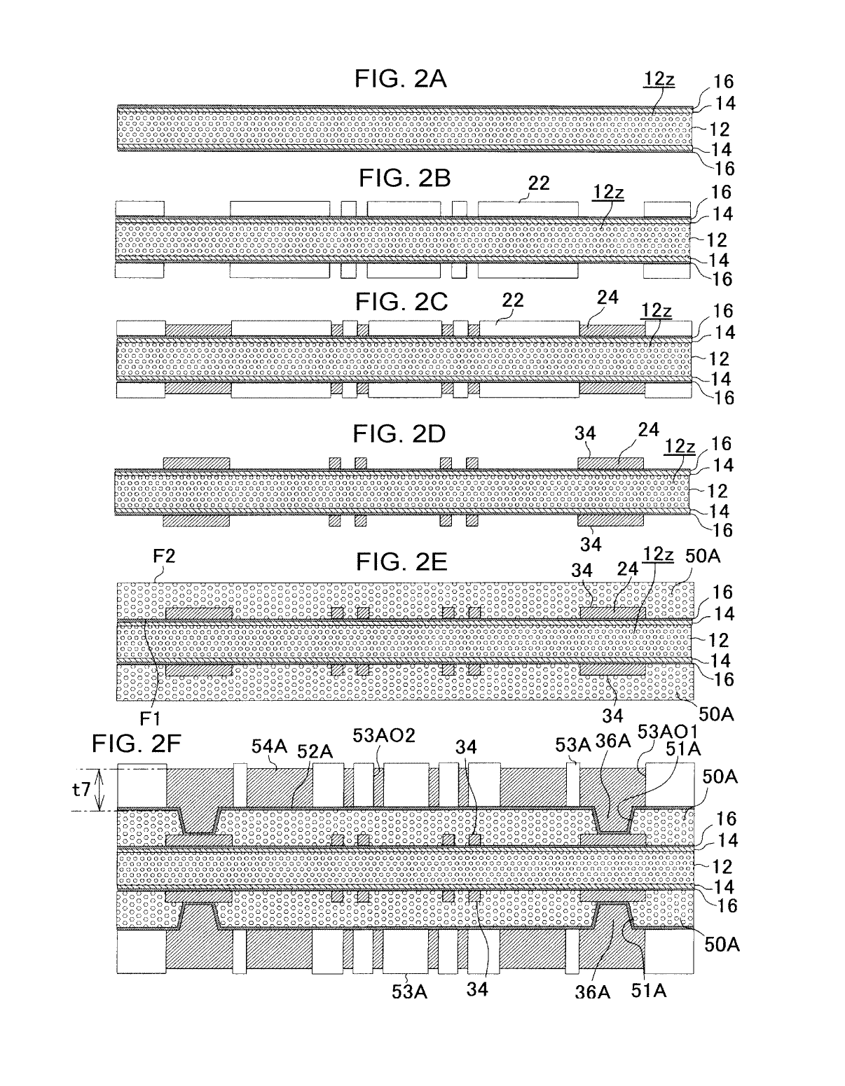

FIG. 2A-5C illustrate a method for manufacturing the printed wiring board of the third embodiment.

A support plate (12z) is prepared. The support plate (12z) is formed by a insulating substrate 12 and a copper foil 14 laminated on both sides of the insulating substrate 12. A copper foil 16 is laminated on the support plate (12z) (FIG. 2A). A plating resist 22 is formed on the copper foil 16. An electrolytic copper plating film 24 is formed by electrolytic copper plating on the copper foil 16 exposed from the plating resist 22 (FIG. 2C). The plating resist is removed. The first conductor layer 34 is formed from the electrolytic copper plating film 24 (FIG. 2D). The thickness (t1) of the first conductor layer 34 is, for example, 2.5 μm. The first resin insulating layer (50A) is formed on the first conductor layer 34 and the copper foil 16 (FIG. 2E). The first resin insulating layer (50A) has the first surface (F1) and the second surface (F2), the first surface (F1) opposing the support plate. The first conductor layer 34 is embedded in the first resin insulating layer (50A).

A first opening (51A) for the first via conductor reaching the first conductor layer 34 is formed in the first resin insulating layer (50A) using laser. The first conductor layer 34 is formed on the copper foil 16. Therefore, heat generated by laser is transmitted from the first conductor layer 34 to the copper foil 16. Therefore, laser is unlikely to penetrate the first conductor layer 34.

An electroless plating film (seed layer) (52A) is formed on the second surface (F2) of the first resin insulating layer (50A) and in the first opening (51A) for the first via conductor. Thereafter, a plating resist (53A) is formed on the electroless plating film (52A). The plating resist has a second opening (53AO1) and a third opening (53AO2). The second opening (53AO1) is formed on the first opening (51A). The second opening (53AO1) and the first opening (51A) are connected to each other. The third opening (53AO2) exposes the seed layer (52A) on the second surface (F2). The third opening (53AO2) is not connected to the first opening (51A). By electrolytic plating, a plating film (electrolytic plating film) (54A) is formed on the electroless plating film (52A) exposed from the plating resist (53A) (FIG. 2F). In this case, since the second opening (53AO1) is formed on the first opening (51A), the first opening (51A) for the first via conductor is filled with the plating film (54A). The plating film (54A) is simultaneously formed in the second opening (53AO1) and the first opening (51A). The plating film (54A) is simultaneously formed in the first opening (51A), the second opening (53AO1) and the third opening (53AO2). In this case, the plating film (54A) is formed in the third opening (53AO2). A thickness sum (t7) (FIG. 2F) of a thickness of the electroless plating film (52A) and a thickness of the plating film (54A) on the second surface (F2) of the first resin insulating layer (50A) is 5 μm or more. In FIG. 2F, the sum (t7) is 5 μm.

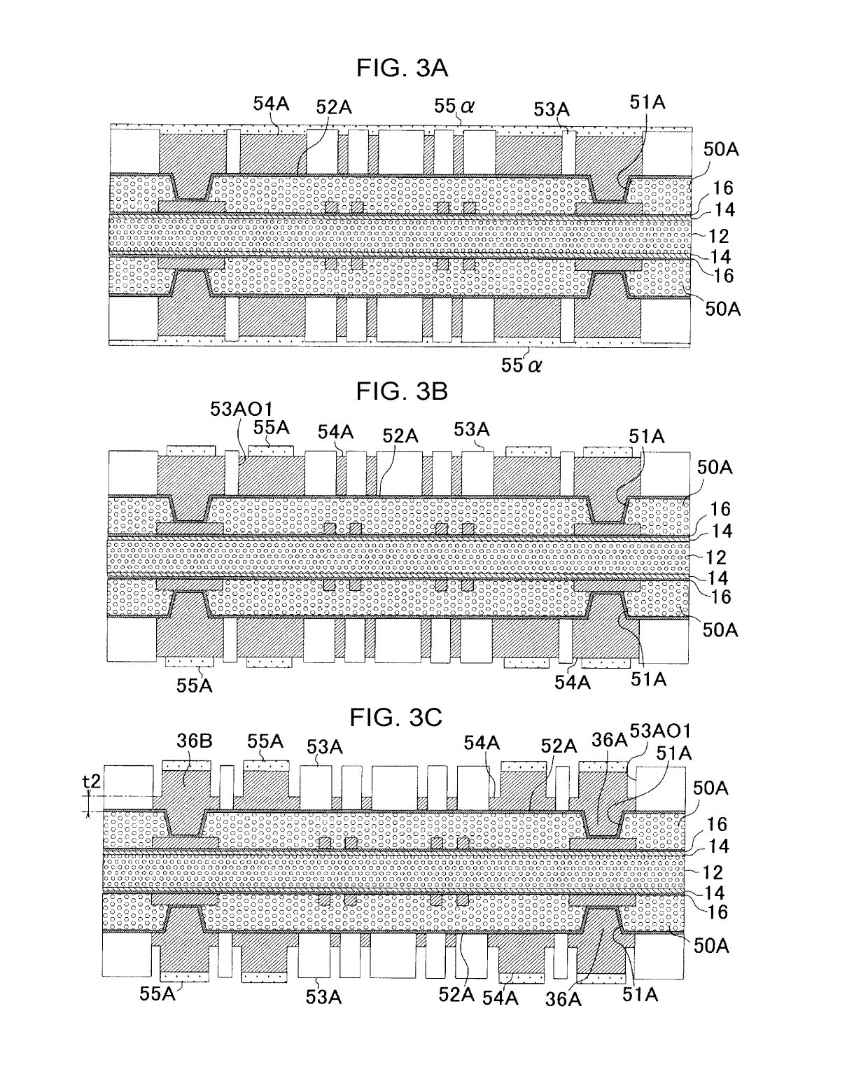

An etching resist composition (55α) is applied on the plating resist (53A) and the plating film (54A) (FIG. 3A). In order to form the second via conductor (36B) and the second conductor layer (58A) from the plating film (54A), an etching resist (55A) is formed on the plating film (54A) (FIG. 3B). The etching resist (55A) is formed from the etching resist composition (55α) using a photographic technology. A position at which the etching resist (55A) is formed is on the second via conductor (36B). By partially thinning the plating film (54A), the second via conductor (36B) and the second conductor layer (58A) are formed. When the second conductor layer (58A) is formed from the plating film (54A), the second conductor layer (58A) is formed by thinning the plating film (54A). Therefore, the etching resist (55A) is not formed on the plating film (54A) for forming the second conductor layer (58A). The plating film 54 that changes to the second conductor layer (58A) is exposed from the etching resist. A size of the etching resist is smaller than a size of the second opening (53AO1) of the plating resist. Therefore, the land is formed. As illustrated in FIG. 3C, a thickness of the plating film (54A) exposed from the etching resist (55A) is reduced. The thickness (t2) of the electroless plating film (52A) and the electrolytic plating film (54A) is adjusted to 2.5 μm.

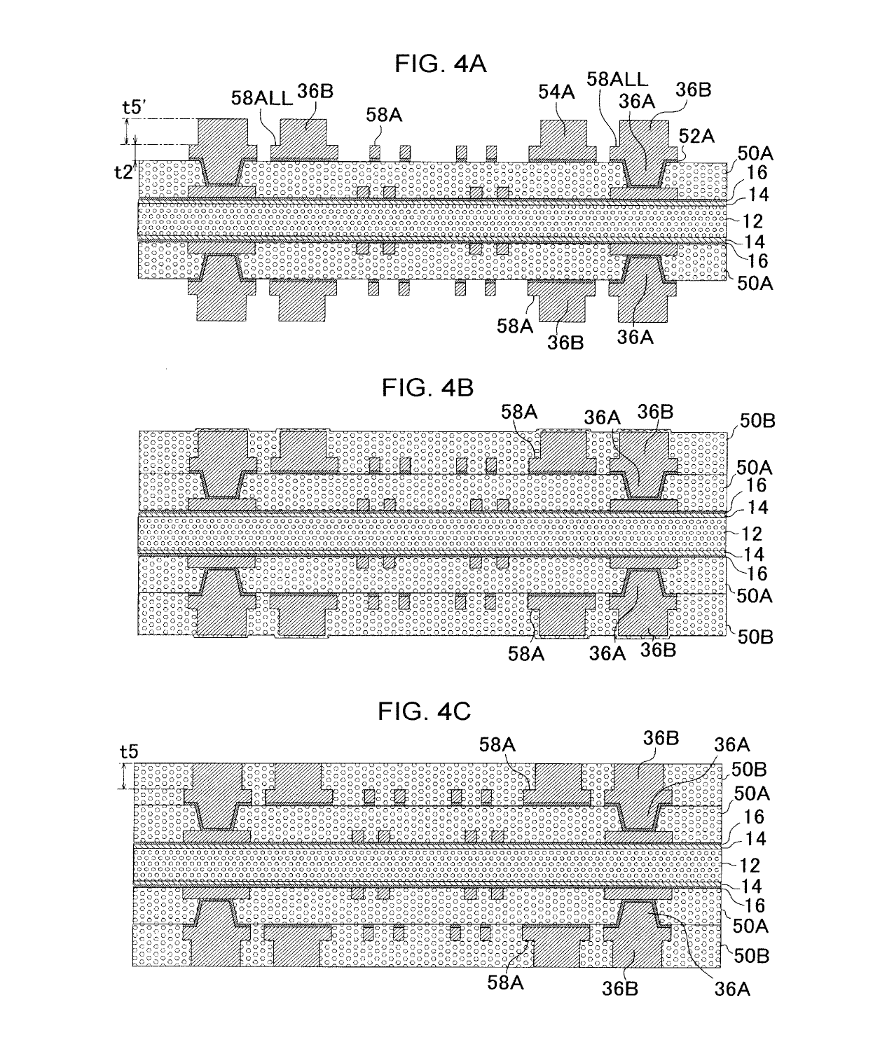

The etching resist 55A) is removed. Thereafter, the plating resist (53A) is removed. Or, the etching resist (55A) is removed after the plating resist (53A) is removed. Or, the plating resist (53A) and the etching resist (55A) are simultaneously removed. The electroless plating film (52A) exposed from the plating film (54A) is removed. The second conductor layer (58A), the second via conductor (36B) and the first via conductor (36A) are formed (FIG. 4A). When the second opening (53AO1) and the first opening (51A) are connected to each other, the first via conductor (36A), the second via conductor (36B) and the land (58ALL) are simultaneously formed. The first via conductor (36A), the second via conductor (36B) and the land (58ALL) are formed from the same plating film (54A). When the third opening (53AO2) and the first opening (51A) are not connected to each other and the third opening (53AO2) is directly formed on the electroless plating film (52A), the second via conductor (36B) and the land (58ALL) are simultaneously formed. The second via conductor (36B) and the land (58ALL) are formed from the same plating film (54A). The first via conductor (36A) and the land (58ALL) may include the seed layer (52A).

In FIG. 4A, the thickness (t2) of the second conductor layer (58A) is 2.5 μm, and a length (t5′) of the second via conductor (36B) is longer than 2.5 μm. In the manufacturing method of the present embodiment, the first via conductor (36A) and the second via conductor (36B) are simultaneously formed. Manufacturing time can be shortened and manufacturing cost can be reduced.

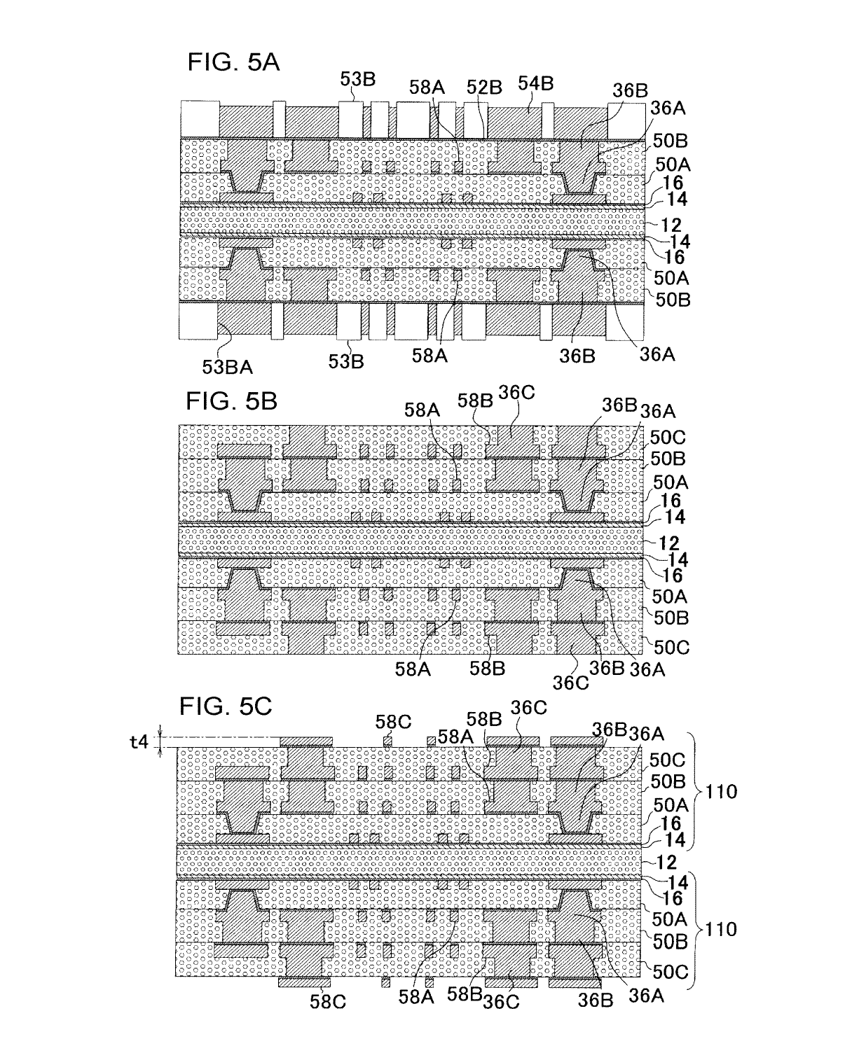

The second resin insulating layer (50B) is formed on the first resin insulating layer (50A) and the second conductor layer (58A) such that the second via conductor (36B) is embedded (FIG. 4B). In order to expose a top part (upper side) of the second via conductor (36B), a surface of the second resin insulating layer (50B) is polished (FIG. 4C). An electroless plating film (52B) is formed on the surface of the second resin insulating layer (50B) and on the top part of the second via conductor (36B). A plating resist (53B) is formed on the electroless plating film (52B). An electrolytic plating film (plating film) (54B) is formed on the electroless plating film (52B) exposed from the plating resist (53B) (FIG. 5A). A thickness of the plating film (54B) exposed from the etching resist is reduced using the same method as that illustrated in FIG. 3A-3C. The etching resist and the plating resist (53B) are removed. The electroless plating film (52B) exposed from the plating film (54B) is removed. The third conductor layer (58B) and the third via conductor (36C) are formed. The third resin insulating layer (50C) is formed on the second resin insulating layer (50B) and the third conductor layer (58B) using the same method as that illustrated in FIGS. 4B and 4C (FIG. 5B). The fourth conductor layer (58C) is formed on the third resin insulating layer (50C) using a semi-additive method or the like (FIG. 5C). The thickness (t4) of the fourth conductor layer (58C) is 2.5 μm. An intermediate substrate 110 including the first resin insulating layer (50A), the second resin insulating layer (50B) and the third resin insulating layer (50C) is formed (FIG. 5C).

The intermediate substrate 110, together with the copper foil 16, is separated from the support plate (12z). The copper foil 16 is removed from the intermediate substrate 110, and the printed wiring board 10 of the third embodiment is formed. The solder resist layer (70F) having the opening 72 for exposing the upper side pad 74 is formed on the third resin insulating layer (50C) of the printed wiring board 10 (FIG. 1B). The solder bump (76F) can be formed on the upper side pad 74. The solder bump (76S) can be formed on the pad (34P) in the first conductor layer 34.

Forming the third via conductor (36C), the third resin insulating layer (50C) and the fourth conductor layer (58C) cab be removed from the method for manufacturing the printed wiring board of the third embodiment. The printed wiring board 10 of the second embodiment is manufactured.

In the manufacturing method of the third embodiment, the first conductor layer 34 is formed in FIG. 2B. Instead, as illustrated in FIG. 6E, the plating resist (53A) having the second opening (53AO1) and the third opening (53AO2) can be formed on the copper foil 16. The plating resist (53A) is formed on a surface that is formed by an upper surface of the copper foil 16. The plating film (54A) for forming the second conductor layer is formed in the openings (53AO1, 53AO2). Thereafter, the same processes as those illustrated in FIGS. 3A-3C and 4A-4C are performed. Thereafter, the third conductor layer (58B) is formed on the second resin insulating layer (50B). As a result, the printed wiring board 10 of the first embodiment is manufactured. In this case, the land does not have a seed layer.

When the printed wiring board 10 of the embodiments is manufactured, the support plate (12z) is present. Therefore, when the printed wiring board of the second embodiment or the third embodiment is manufactured, the first opening (51A) for forming the first via conductor (36A) can be formed using laser. Only for a resin insulating layer that is closest to the support plate (12z), an opening for a via conductor can be formed using laser. It is not essential to form an opening for a via conductor in other resin insulating layers using laser. It is unnecessary to form an opening for a via conductor using laser. For example, the opening for the via conductor (36A) is formed using laser only in the first resin insulating layer (50A). The second resin insulating layer (50B) and the third resin insulating layer (50C) do not have openings for the via conductors (36B, 36C) that are formed using laser. When an opening for a via conductor is formed using laser, the conductor layer has a predetermined thickness. This is because, when the conductor layer is thin, laser is likely to penetrate the conductor layer. According to the embodiments, a via conductor is formed using a method in which laser is not sued. Therefore, the thickness of the conductor layer can be reduced. Therefore, the thickness of the printed wiring board can be reduced.

A manufacturing method of Japanese Patent Laid-Open Publication No. 2014-27250 includes: forming a pillar on a carrier substrate; forming an insulating layer on the carrier substrate such that the pillar is embedded; exposing the pillar by polishing the insulating layer; and forming a circuit on the insulating layer, the circuit connecting to the pillar. When a multilayer coreless substrate is manufactured using the technology of Japanese Patent Laid-Open Publication No. 2014-27250, the formation of the pillar, the formation and the polishing of the insulating layer, and the formation of the circuit are likely to be repeated. For example, due to the polishing, stress is likely to accumulate in the coreless substrate. Warpage of the coreless substrate is expected to increase. Reliability of connection between the pillar and the circuit is likely to decrease.

A printed wiring board according to an embodiment of the present invention includes: a second resin insulating layer that has a third surface and a fourth surface that is on an opposite side of the third surface; a second conductor layer that has an upper surface and a lower surface that is on an opposite side of the upper surface, and is embedded in the second resin insulating layer such that the lower surface is exposed from the third surface; a third conductor layer that is formed on the fourth surface of the second resin insulating layer, and projects from the fourth surface of the second resin insulating layer; and a second via conductor that penetrates the second resin insulating layer and connects the second conductor layer and the third conductor layer. The second conductor layer and the second via conductor are integrally formed. The third conductor layer and the second via conductor are individually formed.

A method for manufacturing a printed wiring board according to an embodiment of the present invention includes: forming a plating resist on a surface, the plating resist having a second opening for a second via conductor and a third opening for a second conductor layer; forming a plating film in the second opening and the third opening; forming an etching resist on the plating film in the second opening; forming the second via conductor and the second conductor layer by thinning the plating film exposed from the etching resist; removing the etching resist; removing the plating resist; forming a second resin insulating layer on the second conductor layer and on the surface such that an upper surface of the second via conductor is exposed; and forming a third conductor layer on the second resin insulating layer, the third conductor layer connecting to the second via conductor.

According to an embodiment of the present invention, the second via conductor and the second conductor layer are integrally formed. The first via conductor, the second via conductor, and the second conductor layer that is sandwiched by the first via conductor and the second via conductor, are integrally formed. Therefore, reliability of connection between the second via conductor and the second conductor layer can be increased. Reliability of connection between the first via conductor and the second via conductor can be increased. Since the number of times of polishing can be reduced, stress in the printed wiring board can be reduced. Warpage of the printed wiring board can be reduced. Yield of the printed wiring board can be increased.

Obviously, numerous modifications and variations of the present invention are possible in light of the above teachings. It is therefore to be understood that within the scope of the appended claims, the invention may be practiced otherwise than as specifically described herein.

What is claimed is:

1. A printed wiring board, comprising:
a resin insulating layer;
a projecting conductor layer formed on a surface of the resin insulating layer such that the projecting conductor layer is projecting from the surface of the resin insulating layer; and
an integral conductor structure formed in the resin insulating layer and comprising a via conductor portion and an embedded conductor layer portion such that the embedded conductor layer portion is embedded in the resin insulating layer on an opposite side of the resin insulating layer with respect to the projecting conductor layer and has an exposed surface exposed from the resin insulating layer and that the via conductor portion is formed through the resin insulating layer and is connecting the embedded conductor layer portion and the projecting conductor layer,
wherein the projecting conductor layer and the integral conductor structure are formed such that the projecting conductor layer and the integral conductor structure are individual conductor structures.

2. A printed wiring board according to claim 1, further comprising:
a first conductor layer; and
a first resin insulating layer formed on the first conductor layer,
wherein the resin insulating layer is formed on the first resin insulating layer such that the embedded conductor layer is formed on the first resin insulating layer, and the integral conductor structure comprises a first via conductor portion formed through the first resin insulating layer and connecting to the first conductor layer, the embedded conductor layer portion embedded in the resin insulating layer, and the via conductor portion formed through the resin insulating layer.

3. A printed wiring board according to claim 2, wherein the integral conductor structure is formed such that the first via conductor portion has a diameter enlarging from the first conductor layer toward the embedded conductor layer portion and that the via conductor portion has a diameter enlarging from the projecting conductor layer toward the embedded conductor layer portion.

4. A printed wiring board according to claim 1, wherein the integral conductor structure is formed such that the embedded conductor layer portion is formed by reducing a thickness of plating for the via conductor portion.

5. A printed wiring board according to claim 2, wherein the integral conductor structure is formed such that the first via conductor portion has a diameter enlarging from the first conductor layer toward the embedded conductor layer portion and that the via conductor portion has a curved side surface curved inward.

6. A printed wiring board according to claim 5, wherein the integral conductor structure is formed such that the via conductor portion has an inflection point on the curved side surface and that the curved surface is reducing a diameter of the via conductor portion toward the inflection point.

7. A printed wiring board according to claim 2, wherein the integral conductor structure is formed such that the first via conductor portion has a diameter enlarging from the first conductor layer toward the embedded conductor layer portion.

8. A printed wiring board according to claim 2, wherein the integral conductor structure is formed such that the via conductor portion has a curved side surface curved inward.

9. A printed wiring board according to claim 8, wherein the integral conductor structure is formed such that the via conductor portion has an inflection point on the curved side surface and that the curved surface is reducing a diameter of the via conductor portion toward the inflection point.

10. A printed wiring board according to claim 2, wherein the integral conductor structure is formed such that the via conductor portion has a diameter enlarging from the projecting conductor layer toward the embedded conductor layer portion.

11. A printed wiring board according to claim 1, wherein the integral conductor structure is formed such that the via conductor portion has a diameter enlarging from the projecting conductor layer toward the embedded conductor layer portion.

12. A printed wiring board according to claim 1, wherein the integral conductor structure is formed in the resin insulating layer such that a distance between the embedded conductor layer portion and the projecting conductor layer is in a range of from 1.5 μm to 3.5 μm.

13. A printed wiring board according to claim 1, wherein the integral conductor structure is formed in the resin insulating layer such that the embedded conductor layer portion has a thickness in a range of from 1.5 μm to 3.5 μm.

14. A printed wiring board according to claim 12, wherein the integral conductor structure is formed in the resin insulating layer such that the embedded conductor layer portion has a thickness in a range of from 1.5 μm to 3.5 μm.

15. A printed wiring board according to claim 2, wherein the integral conductor structure is formed in the resin insulating layer such that a distance between the embedded conductor layer portion and the projecting conductor layer is in a range of from 1.5 μm to 3.5 μm.

16. A printed wiring board according to claim 2, wherein the integral conductor structure is formed in the resin insulating layer such that the embedded conductor layer portion has a thickness in a range of from 1.5 μm to 3.5 μm.

17. A printed wiring board according to claim 2, wherein the integral conductor structure is formed in the resin insulating layer such that the embedded conductor layer portion has a thickness in a range of from 1.5 μm to 3.5 μm.

18. A method for manufacturing a printed wiring board, comprising:
forming a plating resist on a surface of an intermediate wiring board such that the plating resist has an opening portion for an integral conductor structure comprising a via conductor portion and an embedded conductor layer portion;
applying plating in the opening portion of the plating resist such that a plating film is formed in the opening portion of the plating resist;
forming an etching resist for the via conductor portion of the integral conductor structure on the plating film in the opening portion of the plating resist;
reducing a thickness of an exposed portion of the plating film exposed from the etching resist such that the integral conductor structure comprising the via conductor portion and the embedded conductor layer portion is formed in the opening portion of the plating resist;
removing the etching resist from the plating film;
removing the plating resist from the intermediate wiring board;
forming a resin insulating layer on the surface of the intermediate wiring board such that a surface of the via conductor has an exposed surface exposed from the resin insulating layer; and
forming a projecting conductor layer on the resin insulating layer such that the projecting conductor layer connects to the exposed surface of the via conductor portion in the integral conductor structure.

19. A method for manufacturing a printed wiring board according to claim 18, further comprising:
forming the intermediate wiring board,
wherein the forming of the intermediate wiring board comprises forming a first conductor layer, forming a first resin insulating layer on the first conductor layer, forming an opening for a first via conductor portion of the integral conductor structure such that the opening reaches the first conductor layer, and forming a seed layer on a surface of the first resin insulating layer such that the seed layer is formed in the opening for the first via conductor portion of the integral conductor structure, the forming of the plating resist comprises forming the plating resist on the seed layer such that the opening portion of the plating resist is formed to connect to the opening in the first resin insulating layer, and the applying of plating comprises applying plating in the opening in the first resin insulating layer and the opening portion of the plating resist such that the plating film is formed in the opening in the first resin insulating layer and the opening portion of the plating resist.

20. A method for manufacturing a printed wiring board according to claim 18, wherein the forming of the etching resist comprises forming the etching resist such that the etching resist exposes an entire peripheral portion of the plating film formed in the opening portion of the plating resist.
